(19) United States
(12) Patent Application Publication
(10) Pub. No.: US 2019/0207169 A1
(43) Pub. Date: Jul. 4, 2019

(54) PROCESS FOR MAKING AN ORGANIC CHARGE TRANSPORTING FILM

(71) Applicant: Dow Global Technologies LLC, Midland, MI (US)

(72) Inventors: Chun LIU, Midland, MI (US); Peter TREFONAS, Medway, MA (US); Shaoguang FENG, Shanghai (CN); Yang LI, Shanghai (CN); Minrong ZHU, Shanghai (CN); Robert David GRIGG, Midland, MI (US); Liam P. SPENCER, Lake Jackson, TX (US); David D. DEVORE, Midland, MI (US); Ashley INMAN, MIdland, MI (US); Emad AQAD, Northborough, MA (US)

(21) Appl. No.: 16/311,900

(22) PCT Filed: Jun. 28, 2016
(86) PCT No.: PCT/CN2016/087413

§ 371 Date: Dec. 20, 2018

(51) Int. Cl. H01L 51/56; H01L 51/00; C08G 61/12

(52) U.S. Cl. CPC H01L 51/56; H01L 51/0003; H01L 51/5056; H01L 51/0039; C08G 61/124; H01L 51/0025

(57) ABSTRACT

A method for producing an organic charge transporting film. The method comprises steps of: (a) applying to a substrate a first polymer resin which has substituents which are sulfonic acids, sulfonic acid salts or esters of sulfonic acids; and (b) applying over the first polymer resin a second polymer resin having M_{w} at least 3,000 and comprising arylmethoxy linkages.

### FIELD OF THE INVENTION

The present invention relates to a process for preparing an organic charge transporting film.

### BACKGROUND OF THE INVENTION

There is a need for an efficient process for manufacturing an organic charge transporting film for use in a flat panel organic light emitting diode (OLED) display. Solution processing is one of the leading technologies for fabricating large flat panel OLED displays by deposition of OLED solution onto a substrate to form a thin film followed by cross-linking and polymerization. Currently, solution processable polymeric materials are cross-linkable organic charge transporting compounds. For example, U.S. Pat. No. 7,037,994 discloses an antireflection film-forming formulation comprising at least one polymer containing an acetoxymethylacenaphthylene or hydroxyl methyl acenaphthylene repeating unit and a thermal or photo acid generator (TAG, PAG) in a solvent. However, this reference does not disclose the method described herein.

### SUMMARY OF THE INVENTION

The present invention provides a method for producing an organic charge transporting film; said method comprising steps of: (a) applying to a substrate a first polymer resin which has substituents which are sulfonic acids, sulfonic acid salts or esters of sulfonic acids; and (b) applying over the first polymer resin a second polymer resin having M_{w} at least 3,000 and comprising arylmethoxy linkages.

### DETAILED DESCRIPTION OF THE INVENTION

Percentages are weight percentages (wt %) and temperatures are in ° C., unless specified otherwise. Operations were performed at room temperature (20-25° C.), unless specified otherwise. Boiling points are measured at atmospheric pressure (ca. 101 kPa). Molecular weights are in Daltons and molecular weights of polymers are determined by Size Exclusion Chromatography using polystyrene standards. The second polymer resin is a monomer, oligomer or polymer which can be cured to form a cross-linked film. Preferably the second polymer resin comprises polymerized units of monomers that have at least one group which is polymerizable by addition polymerization. Examples of polymerizable groups include an ethenyl group (preferably attached to an aromatic ring), benzocyclobutenes, acrylate or methacrylate groups, trifluorovinylether, cinnamate/chalcone, diene, ethoxyethyne and 3-ethoxy-4-methylcyclobut-2-enone. Preferred monomers contain at least one of the following structures

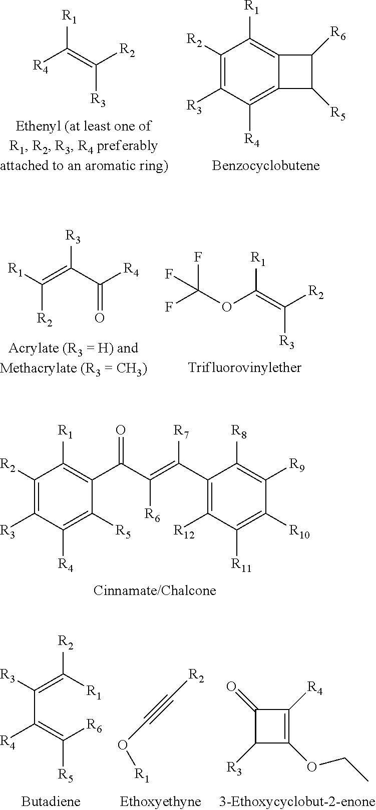

where “R” groups independently are hydrogen, deuterium, C₁-C₃₀ alkyl, hetero-atom substituted C₁-C₃₀ alkyl, C₁-C₃₀ aryl, hetero-atom substituted C₁-C₃₀ aryl or represent another part of the resin structure; preferably hydrogen, deuterium, C₁-C₂₀ alkyl, hetero-atom substituted C₁-C₂₀ alkyl, C₁-C₂₀ aryl, hetero-atom substituted C₁-C₂₀ aryl or represent another part of the resin structure; preferably hydrogen, deuterium, C₁-C₁₀ alkyl, hetero-atom substituted C₁-C₁₀ alkyl, C₁-C₁₀ aryl, hetero-atom substituted C₁-C₁₀ aryl or represent another part of the resin structure; preferably hydrogen, deuterium, C₁-C₄ alkyl, hetero-atom substituted C₁-C₄ alkyl, or represent another part of the resin structure. In one preferred embodiment of the invention, “R” groups may be connected to form fused ring structures.

An arylmethoxy linkage is a linkage having at least one benzylic carbon atom attached to an oxygen atom. Preferably, the arylmethoxy linkage is an ether, an ester or a benzyl alcohol. Preferably, the arylmethoxy linkage has two benzylic carbon atoms attached to an oxygen atom. A benzylic carbon atom is a carbon atom which is not part of an aromatic ring and which is attached to a ring carbon of an aromatic ring having from 5 to 30 carbon atoms (preferably 5 to 20), preferably a benzene ring.

An “organic charge transporting compound” is a material which is capable of accepting an electrical charge and transporting it through the charge transport layer. Examples of charge transporting compounds include “electron transporting compounds” which are charge transporting compounds capable of accepting an electron and transporting it through the charge transport layer, and “hole transporting compounds” which are charge transporting compounds capable of transporting a positive charge through the charge transport layer. Preferably, organic charge transporting compounds. Preferably, organic charge transporting compounds have at least 50 wt % aromatic rings (measured as the molecular weight of all aromatic rings divided by total molecular weight; non-aromatic rings fused to aromatic rings are included in the molecular weight of aromatic rings), preferably at least 60%, preferably at least 70%, preferably at least 80%, preferably at least 90%. Preferably the resins are organic charge transporting compounds.

In a preferred embodiment of the invention, some or all materials used, including solvents and resins, are enriched in deuterium beyond its natural isotopic abundance. All compound names and structures which appear herein are intended to include all partially or completely deuterated analogs.

Preferably, the second polymer resin has M_{w} at least 5,000, preferably at least 10,000, preferably at least 20,000; preferably no greater than 10,000,000, preferably no greater than 1,000,000, preferably no greater than 500,000, preferably no greater than 400,000, preferably no greater than 300,000, preferably no greater than 200,000, preferably no greater than 100,000. Preferably, the second polymer resin comprises at least 50% (preferably at least 60%, preferably at least 70%, preferably at least 80%, preferably at least 90%) polymerized monomers which contain at least five aromatic rings, preferably at least six, preferably no more than 20, preferably no more than 15; other monomers not having this characteristic may also be present. A cyclic moiety which contains two or more fused rings is considered to be a single aromatic ring, provided that all ring atoms in the cyclic moiety are part of the aromatic system. For example, naphthyl, carbazolyl and indolyl are considered to be single aromatic rings, but fluorenyl is considered to contain two aromatic rings because the carbon atom at the 9-position of fluorene is not part of the aromatic system. Preferably, the second polymer resin comprises at least 50% (preferably at least 70%) polymerized monomers which contain at least one oftriarylamine, carbazole, indole and fluorene ring systems.

Preferably, the second polymer resin comprises a first monomer of formula NAr¹Ar²Ar³, wherein Ar¹, Ar² and Ar³ independently are C₆-C₅₀ aromatic substituents and at least one of Ar¹, Ar² and Ar³ contains a vinyl group attached to an aromatic ring. Preferably, the second polymer resin comprises at least 50% of the first monomer, preferably at least 60%, preferably at least 70%, preferably at least 80%, preferably at least 90%. Preferably, the second polymer resin is a copolymer of the first monomer and a second monomer of formula (I)

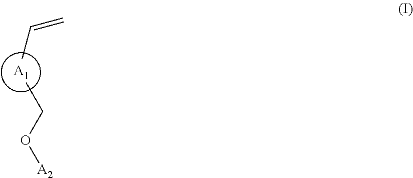

wherein A₁ is an aromatic ring system having from 5 to 20 carbon atoms and in which the vinyl group and the —CH₂OA₂ group are attached to aromatic ring carbons and A₂ is hydrogen or a C₁-C₂₀ organic substituent group. Preferably, A₁ has five or six carbon atoms, preferably it is a benzene ring. Preferably, A₂ is hydrogen or a C₁-C₁₅ organic substituent group, preferably containing no atoms other than carbon, hydrogen, oxygen and nitrogen. Preferably, the monomer of formula NAr¹Ar²Ar³ contains a total of 4 to 20 aromatic rings; preferably at least 5 preferably at least 6; preferably no more than 18, preferably no more than 15, preferably no more than 13. Preferably, each of Ar¹, Ar² and Ar³ independently contains at least 10 carbon atoms, preferably at least 12; preferably no more than 45, preferably no more than 42, preferably no more than 40. In a preferred embodiment, each of Ar² and Ar³ independently contains at least 10 carbon atoms, preferably at least 15, preferably at least 20; preferably no more than 45, preferably no more than 42, preferably no more than 40; and Ar^{t} contains no more than 35 carbon atoms, preferably no more than 25, preferably no more than 15. Aliphatic carbon atoms, e.g., C₁-C₆ hydrocarbyl substituents or non-aromatic ring carbon atoms (e.g., the 9-carbon of fluorene), are included in the total number of carbon atoms in an Ar substituent. Ar groups may contain heteroatoms, preferably N, O or S; preferably N; preferably Ar groups contain no heteroatoms other than nitrogen. Preferably, only one vinyl group is present in the compound of formula NAr¹Ar²Ar³. Preferably, Ar groups comprise one or more of biphenylyl, fluorenyl, phenylenyl, carbazolyl and indolyl. In a preferred embodiment of the invention, two of Ar¹, Ar² and Ar³ are connected by at least one covalent bond. An example of this is the structure shown below

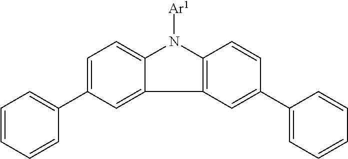

When a nitrogen atom in one of the aryl substituents is a triarylamine nitrogen atom, the Ar¹, Ar² and Ar³ groups can be defined in different ways depending on which nitrogen atom is considered to be the nitrogen atom in the formula NAr¹Ar²Ar³. In this case, the nitrogen atom and Ar groups are to be construed so as to satisfy the claim limitations.

Preferably, Ar¹, Ar² and Ar³ collectively contain no more than five nitrogen atoms, preferably no more than four, preferably no more than three.

In a preferred embodiment, the polymer comprises a monomer having formula (I) in which A₂ is a substituent of formula NAr¹Ar²Ar³, as defined above, preferably linked to oxygen via an aromatic ring carbon or a benzylic carbon.

In a preferred embodiment of the invention, the formulation further comprises a monomer or oligomer having M_{w} less than 5,000, preferably less than 3,000, preferably less than 2,000, preferably less than 1,000; preferably a crosslinker having at least three polymerizable vinyl groups.

Preferably, the polymer resins are at least 99% pure, as measured by liquid chromatography/mass spectrometry (LC/MS) on a solids basis, preferably at least 99.5%, preferably at least 99.7%. Preferably, the formulation of this invention contains no more than 10 ppm of metals, preferably no more than 5 ppm.

Preferred second polymer resins useful in the present invention include, e.g., the following structures.

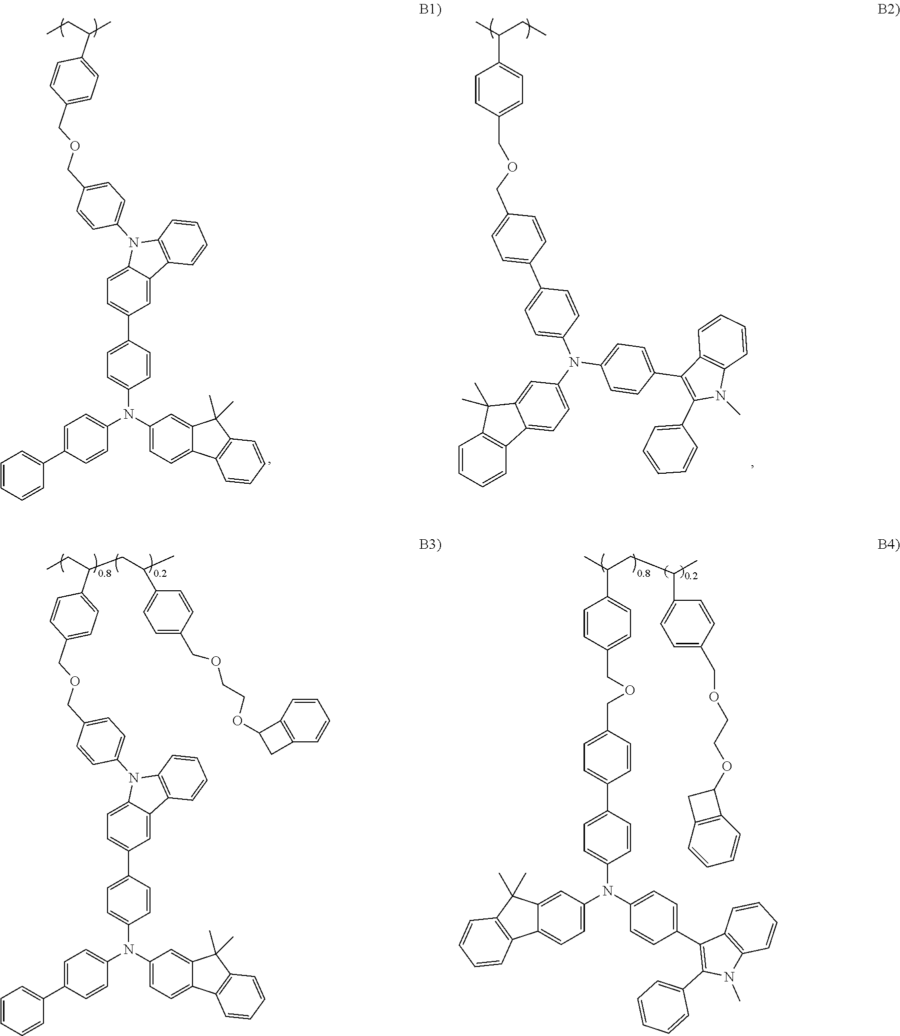

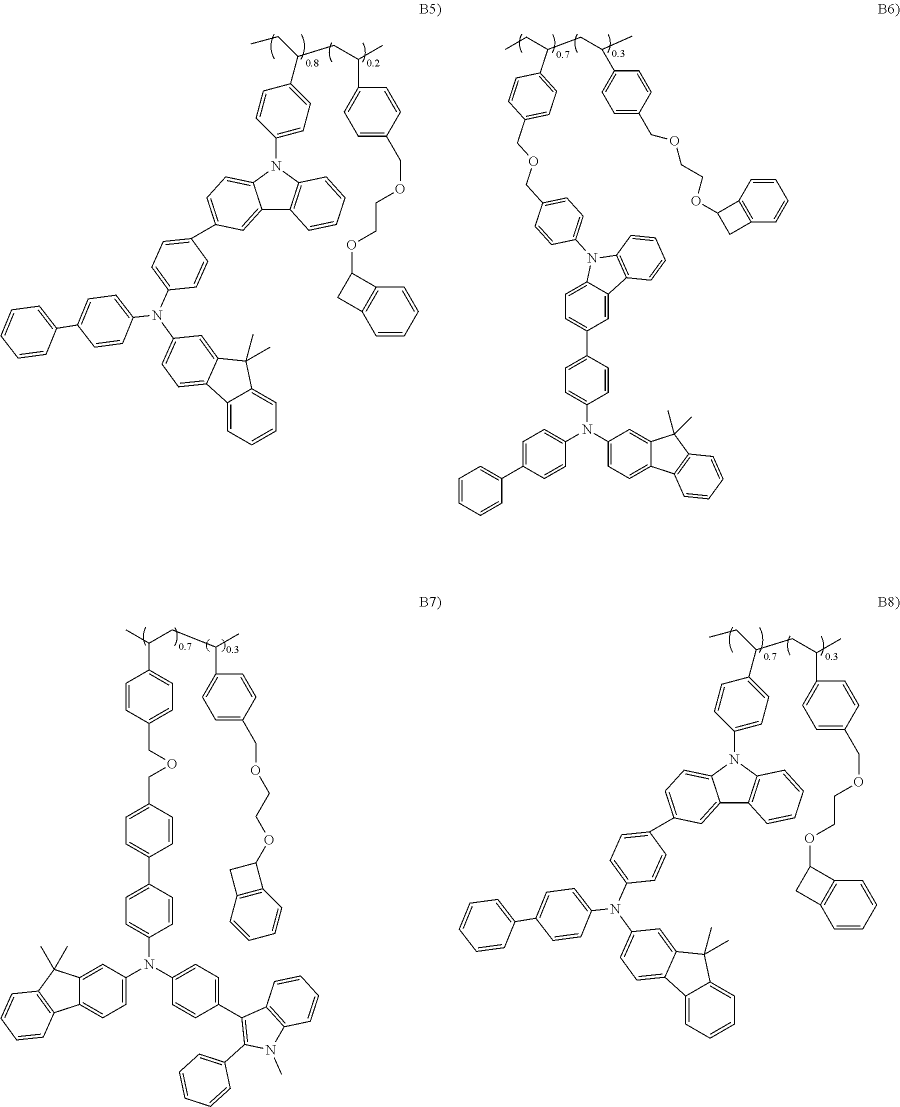

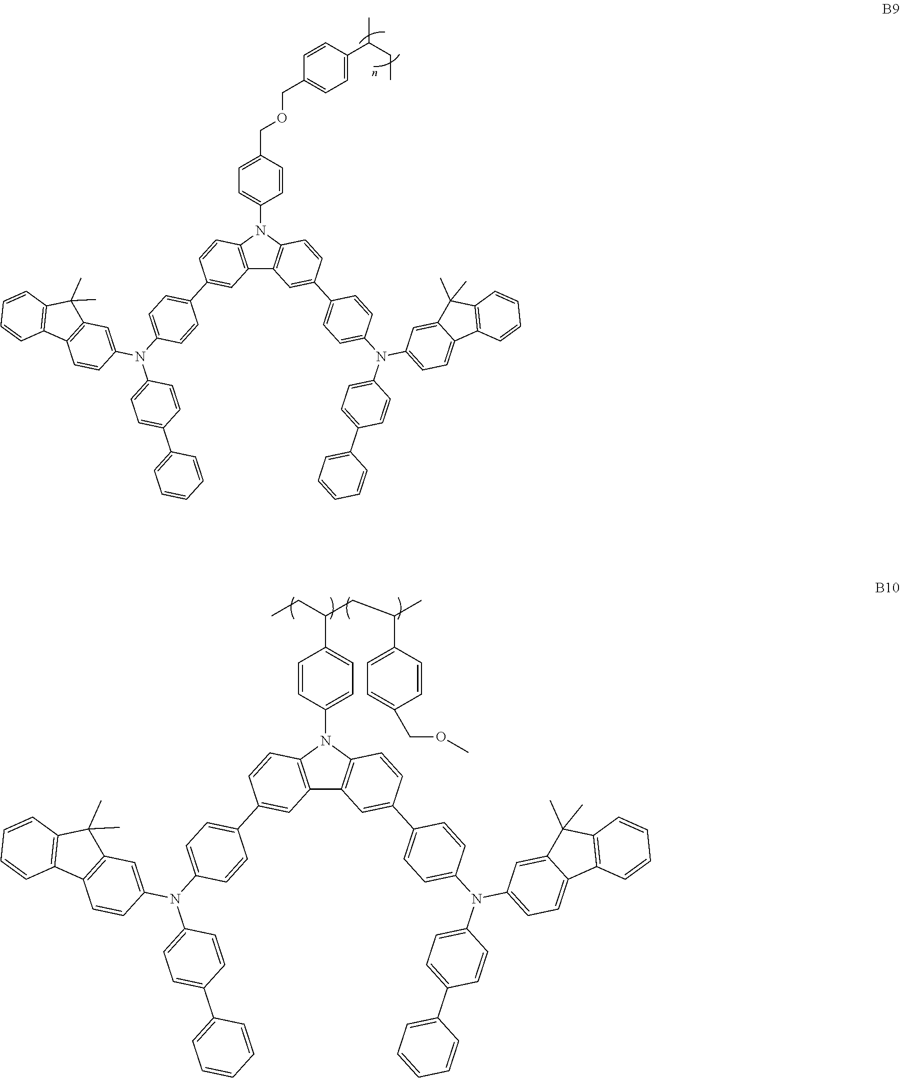

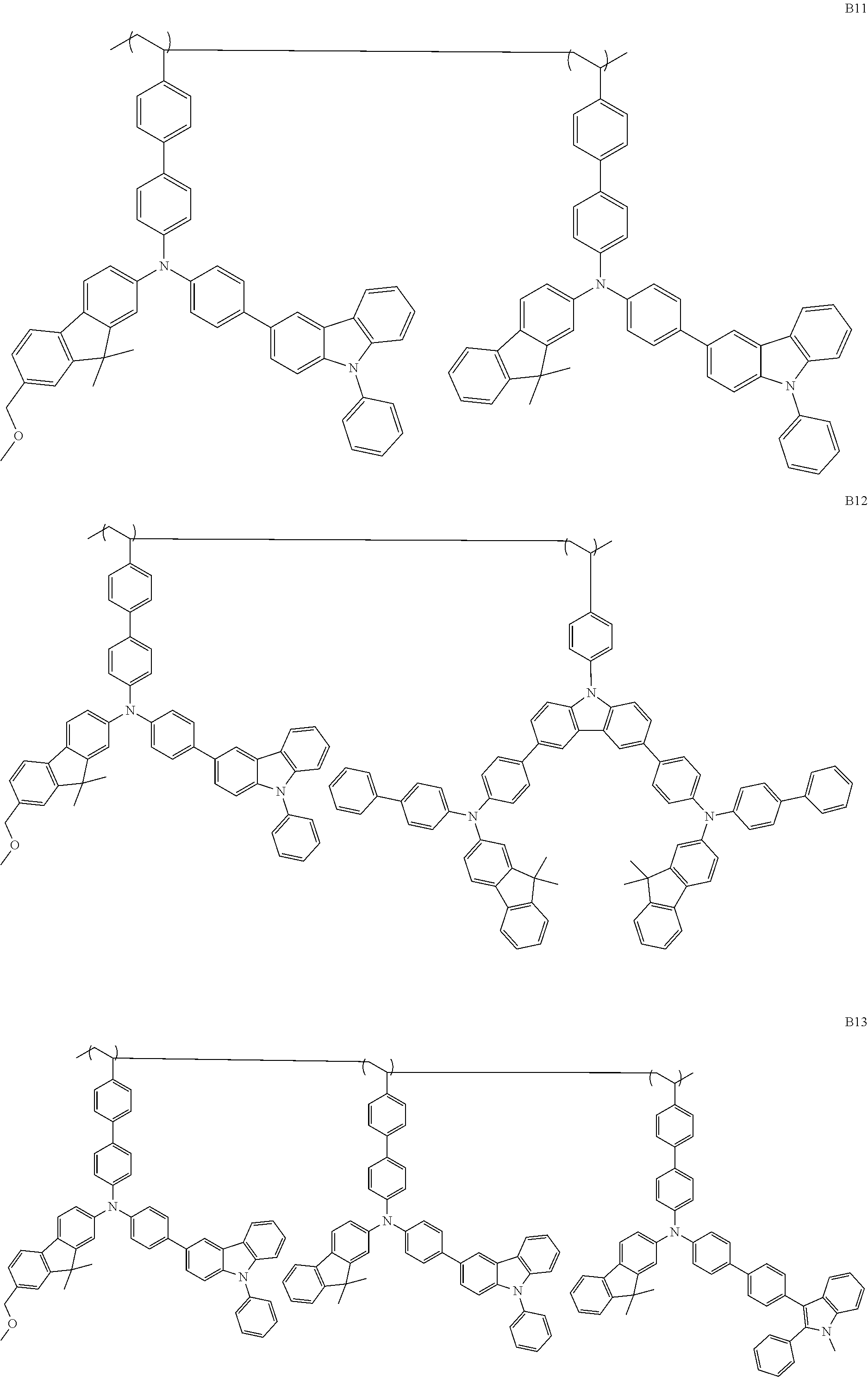

Crosslinking agents which are not necessarily charge transporting compounds may be included in the formulation as well. Preferably, these crosslinking agents have at least 60 wt % aromatic rings (as defined previously), preferably at least 70%, preferably at least 75 wt %. Preferably, the crosslinking agents have from three to five polymerizable groups, preferably three or four. Preferably, the polymerizable groups are ethenyl groups attached to aromatic rings. Preferred crosslinking agents are shown below

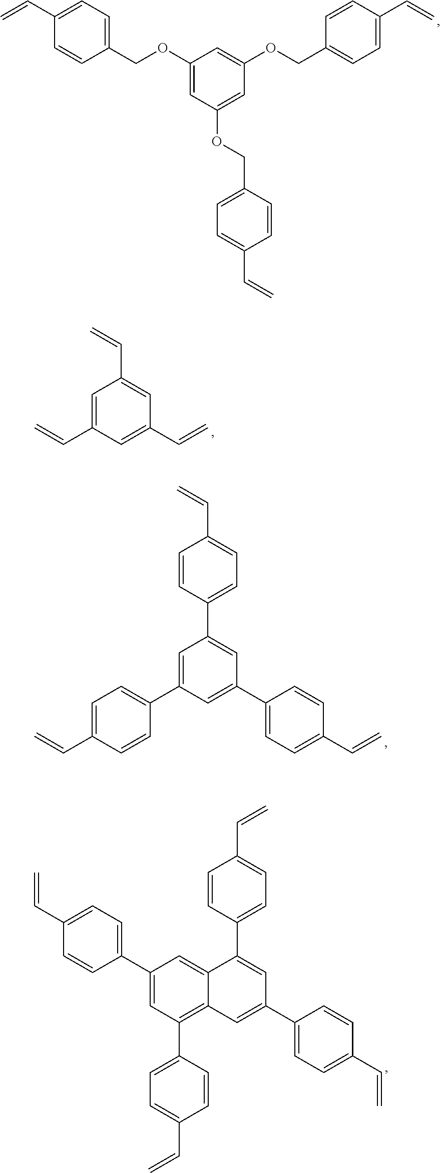

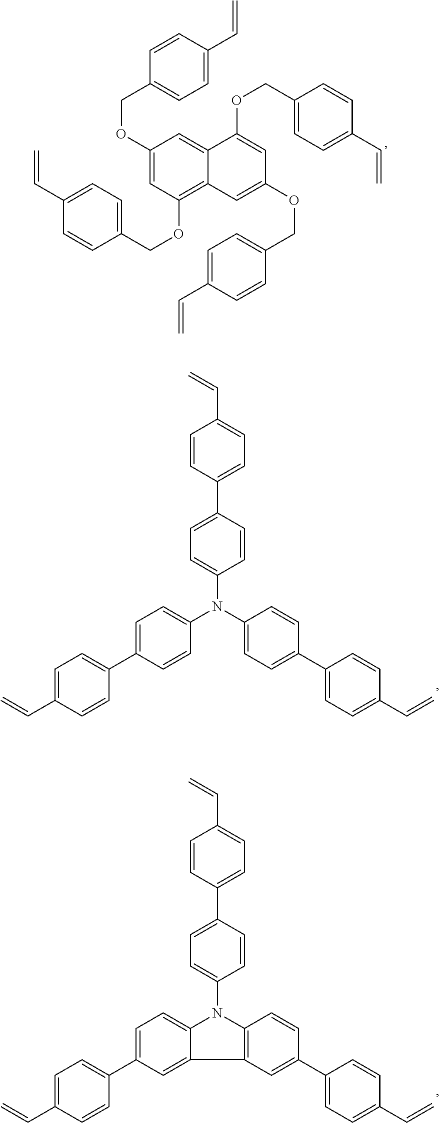

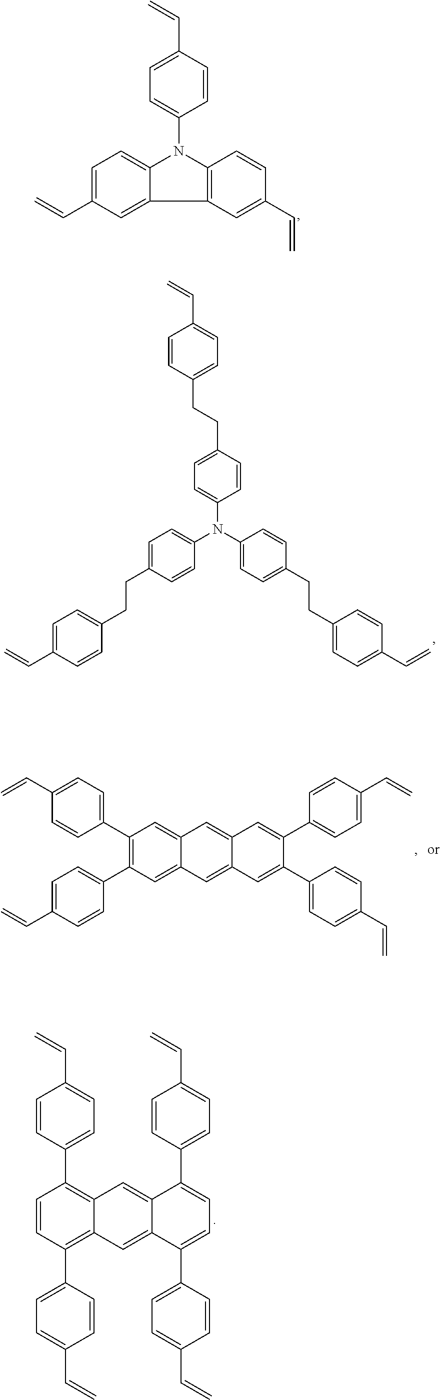

Preferably, the second polymer resin is applied directly on the first polymer resin with no intermediate film.

Preferably, the first polymer resin is a mixture of at least two polymers. Preferably, M_{w} of a first polymer which has substituents which are sulfonic acids, sulfonic acid salts or esters of sulfonic acids is from 2,000 to 1,000,000; preferably at least 4,000, preferably at least 6,000; preferably no more than 500,000, preferably no more than 300,000. Preferably, the first polymer comprises polymerized units of styrene substituted by sulfonic acid, sulfonic acid salt or sulfonic acid ester substituents. Preferably, the first polymer resin further comprises a second polymer which does not have substituents which are sulfonic acids, sulfonic acid salts or esters of sulfonic acids. Preferably, M_{w} of a second polymer is from 2,000 to 1,000,000; preferably at least 4,000, preferably at least 6,000; preferably no more than 500,000, preferably no more than 300,000. Preferably, the second polymer comprises polymerized monomer units containing aromatic rings, preferably thiophene, pyrrole or polyaniline.

Preferably, the amount of the acidic first polymer is from 50 to 95 wt % of the weight of the first polymer resin, preferably at least 70 wt %, preferably at least 85 wt %.

Preferably, solvents used in the formulation have a purity of at least 99.8%, as measured by gas chromatography-mass spectrometry (GC/MS), preferably at least 99.9%. Preferably, solvents have an RED value (relative energy difference (vs. polymer) as calculated from Hansen solubility parameter using CHEMCOMP v2.8.50223.1) less than 1.2, preferably less than 1.0. Preferred solvents include aromatic hydrocarbons and aromatic-aliphatic ethers, preferably those having from six to twenty carbon atoms. Anisole, xylene and toluene are especially preferred solvents.

Preferably, the percent solids of the formulation, i.e., the percentage of monomers and polymers relative to the total weight of the formulation, is from 0.5 to 20 wt %; preferably at least 0.8 wt %, preferably at least 1 wt %, preferably at least 1.5 wt %; preferably no more than 15 wt %, preferably no more than 10 wt %, preferably no more than 7 wt %, preferably no more than 4 wt %. Preferably, the amount of solvent(s) is from 80 to 99.5 wt %; preferably at least 85 wt %, preferably at least 90 wt %, preferably at least 93 wt %, preferably at least 94 wt %; preferably no more than 99.2 wt %, preferably no more than 99 wt %, preferably no more than 98.5 wt %.

The present invention is further directed to an organic charge transporting film and a process for producing it by coating the formulation on a surface, preferably another organic charge transporting film, and Indium-Tin-Oxide (ITO) glass or a silicon wafer. The film is formed by coating the formulation on a surface, baking at a temperature from 50 to 150° C. (preferably 80 to 120° C.), preferably for less than five minutes, followed by thermal cross-linking at a temperature from 120 to 280° C.; preferably at least 140° C., preferably at least 160° C., preferably at least 170° C.; preferably no greater than 230° C., preferably no greater than 215° C.

Preferably, the thickness of the polymer films produced according to this invention is from 1 nm to 100 microns, preferably at least 10 nm, preferably at least 30 nm, preferably no greater than 10 microns, preferably no greater than 1 micron, preferably no greater than 300 nm. The spin-coated film thickness is determined mainly by the solid contents in solution and the spin rate. For example, at a 2000 rpm spin rate, 2, 5, 8 and 10 wt % polymer resin formulated solutions result in the film thickness of 30, 90, 160 and 220 nm, respectively. The wet film shrinks by 5% or less after baking and cross-linking.

### EXAMPLES

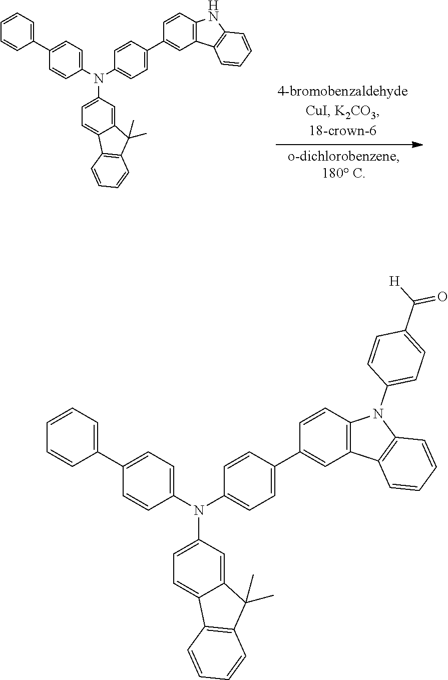 [SMILES: CC1(C)c2ccccc2-c2ccc(N(c3ccc(-c4ccccc4)cc3)c3ccc(-c4ccc5[nH]c6ccccc6c5c4)cc3)cc21 ; CC1(C)c2ccccc2-c2ccc(N(c3ccc(-c4ccccc4)cc3)c3ccc(-c4ccc5c(c4)c4ccccc4n5-c4ccc(C=O)cc4)cc3)cc21]

### Synthesis of 4-(3-(4-([1,1′-biphenyl]-4-yl(9,9-dimethyl-9H-fluoren-2-yl)amino)phenyl)-9H-carbazol-9-yl)benzaldehyde

A round-bottom flask was charged with N-(4-(9H-carbazol-3-yl)phenyl)-N-([1,1′-biphenyl]-4-yl)-9,9-dimethyl-9H-fluoren-2-amine (2.00 g 3.318 mmol, 1.0 equiv), 4-bromobenzaldehyde (0.737 g, 3.982 mmol, 1.2 equiv), CuI (0.126 g 0.664 mmol, 0.2 equiv), potassium carbonate (1.376 g 9.954 mmol, 3.0 equiv), and 18-crown-6 (86 mg 10 mol %). The flask was flushed with nitrogen and connected to a reflux condenser. 10.0 mL dry, degassed 1,2-dichlorobenzene was added, and the mixture was refluxed for 48 hours. The cooled solution was quenched with sat. aq. NH₄Cl, and extracted with dichloromethane. Combined organic fractions were dried, and solvent was removed by distillation. The crude residue was purified by chromatography on silica gel (hexane/chloroform gradient), and gave a bright yellow solid product (2.04 g). The product had the following characteristics: ¹H-NMR (500 MHz, CDCl₃): δ 10.13 (s, 1H), 8.37 (d, J=2.0 Hz, 1H), 8.20 (dd, J=7.7, 1.0 Hz, 1H), 8.16 (d, J=8.2 Hz, 2H), 7.83 (d, J=8.1 Hz, 2H), 7.73-7.59 (m, 7H), 7.59-7.50 (m, 4H), 7.50-7.39 (m, 4H), 7.39-7.24 (m, 10H), 7.19-7.12 (m, 1H), 1.47 (s, 6H). ¹³C-NMR (126 MHz, CDCl₃): δ 190.95, 155.17, 153.57, 147.21, 146.98, 146.69, 143.38, 140.60, 140.48, 139.28, 138.93, 135.90, 135.18, 134.64, 134.46, 133.88, 131.43, 128.76, 127.97, 127.81, 126.99, 126.84, 126.73, 126.65, 126.54, 126.47, 125.44, 124.56, 124.44, 124.12, 123.98, 123.63, 122.49, 120.96, 120.70, 120.57, 119.47, 118.92, 118.48, 110.05, 109.92, 46.90, 27.13.

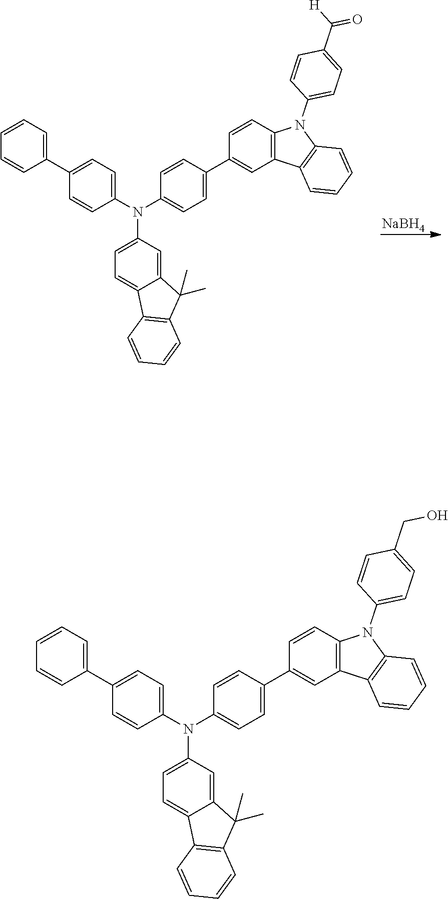 [SMILES: CC1(C)c2ccccc2-c2ccc(N(c3ccc(-c4ccccc4)cc3)c3ccc(-c4ccc5c(c4)c4ccccc4n5-c4ccc(C=O)cc4)cc3)cc21 ; "NaBH4" ; CC1(C)c2ccccc2-c2ccc(N(c3ccc(-c4ccccc4)cc3)c3ccc(-c4ccc5c(c4)c4ccccc4n5-c4ccc(CO)cc4)cc3)cc21]

### Synthesis of (4-(3-(4-([1,1′-biphenyl]-4-yl(9,9-dimethyl-9H-fluoren-2-yl)amino)phenyl)-9H-carbazol-9-yl)phenyl)methanol

A round-bottom flask was charged with Formula 1 (4.36 g, 6.17 mmol, 1.00 equiv) under a blanket of nitrogen. The material was dissolved in 40 mL 1:1 THF:EtOH. borohydride (0.280 g, 7.41 mmol, 1.20 equiv) was added in portions and the material was stirred for 3 hours. The reaction mixture was cautiously quenched with 1M HCl, and the product was extracted with portions of dichloromethane. Combined organic fractions were washed with sat. aq. sodium bicarbonate, dried with MgSO₄ and concentrated to a crude residue. The material was purified by chromatography (hexane/dichloromethane gradient), and gave a white solid product (3.79 g). The product had the following characteristics: ¹H-NMR (500 MHz, CDCl₃): δ 8.35 (s, 1H), 8.19 (dt, J=7.8, 1.1 Hz, 1H), 7.73-7.56 (m, 11H), 7.57-7.48 (m, 2H), 7.48-7.37 (m, 6H), 7.36-7.23 (m, 9H), 7.14 (s, 1H), 4.84 (s, 2H), 1.45 (s, 6H). ¹³C-NMR (126 MHz, CDCl₃): δ 155.13, 153.56, 147.24, 147.02, 146.44, 141.27, 140.60, 140.11, 140.07, 138.94, 136.99, 136.33, 135.06, 134.35, 132.96, 128.73, 128.44, 127.96, 127.76, 127.09, 126.96, 126.79, 126.62, 126.48, 126.10, 125.15, 124.52, 123.90, 123.54, 123.49, 122.46, 120.66, 120.36, 120.06, 119.43, 118.82, 118.33, 109.95, 109.85, 64.86, 46.87, 27.11.

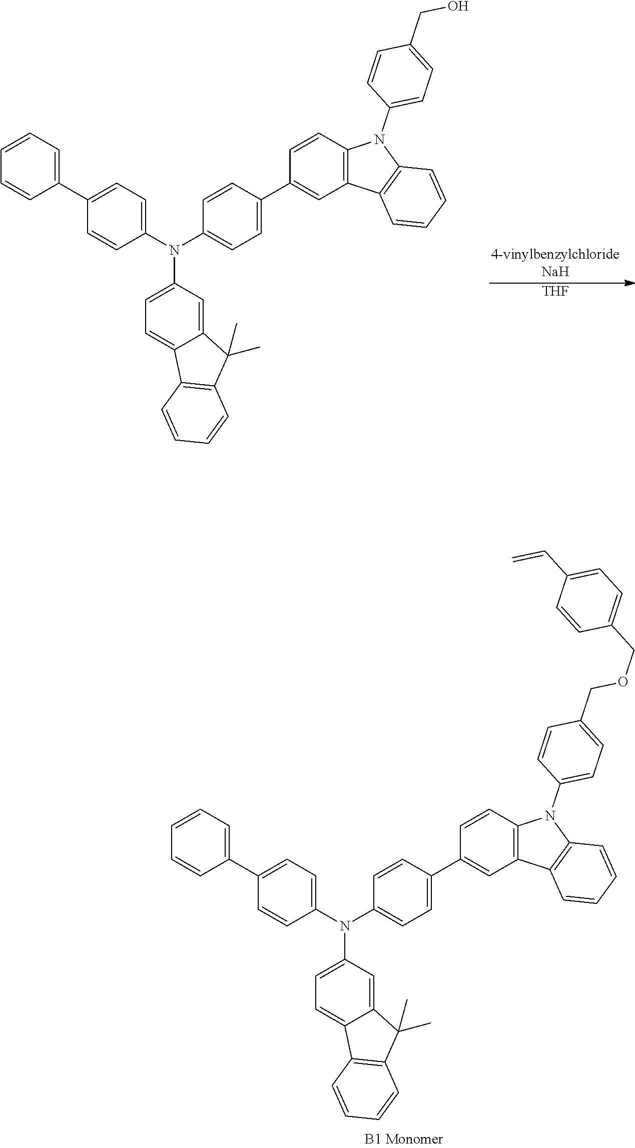

### Synthesis of N-([1,1′-biphenyl]-4-yl)-9,9-dimethyl-N-(4-(9-(4-(((4-vinylbenzyl)oxy)methyl)phenyl)-9H-carbazol-3-yl)phenyl)-9H-fluoren-2-amine (B1 Monomer)

In a nitrogen-filled glovebox, a 100 mL round-bottom flask was charged with Formula 2 (4.40 g, 6.21 mmol, 1.00 equiv) and 35 mL THF. Sodium hydride (0.224 g, 9.32 mmol, 1.50 equiv) was added in portions, and the mixture was stirred for 30 minutes. A reflux condenser was attached, the unit was sealed and removed from the glovebox. 4-vinylbenzyl chloride (1.05 mL, 7.45 mmol, 1.20 equiv) was injected, and the mixture was refluxed until consumption of starting material. The reaction mixture was cooled (iced bath) and cautiously quenched with isopropanol. Sat. aq. NH₄Cl was added, and the product was extracted with ethyl acetate. Combined organic fractions were washed with brine, dried with MgSO₄, filtered, concentrated, and purified by chromatography on silica. The product had the following characteristics: ¹H-NMR (400 MHz, CDCl₃): δ 8.35 (s, 1H), 8.18 (dt, J=7.8, 1.0 Hz, 1H), 7.74-7.47 (m, 14H), 7.47-7.35 (m, 11H), 7.35-7.23 (m, 9H), 7.14 (s, 1H), 6.73 (dd, J=17.6, 10.9 Hz, 1H), 5.76 (dd, J=17.6, 0.9 Hz, 1H), 5.25 (dd, J=10.9, 0.9 Hz, 1H), 4.65 (s, 4H), 1.45 (s, 6H). ¹³C-NMR (101 MHz, CDCl₃): δ 155.13, 153.56, 147.25, 147.03, 146.43, 141.28, 140.61, 140.13, 138.94, 137.64, 137.63, 137.16, 137.00, 136.48, 136.37, 135.06, 134.35, 132.94, 129.21, 128.73, 128.05, 127.96, 127.76, 126.96, 126.94, 126.79, 126.62, 126.48, 126.33, 126.09, 125.14, 124.54, 123.89, 123.54, 123.48, 122.46, 120.66, 120.34, 120.04, 119.44, 118.82, 118.31, 113.92, 110.01, 109.90, 72.33, 71.61, 46.87, 27.11.

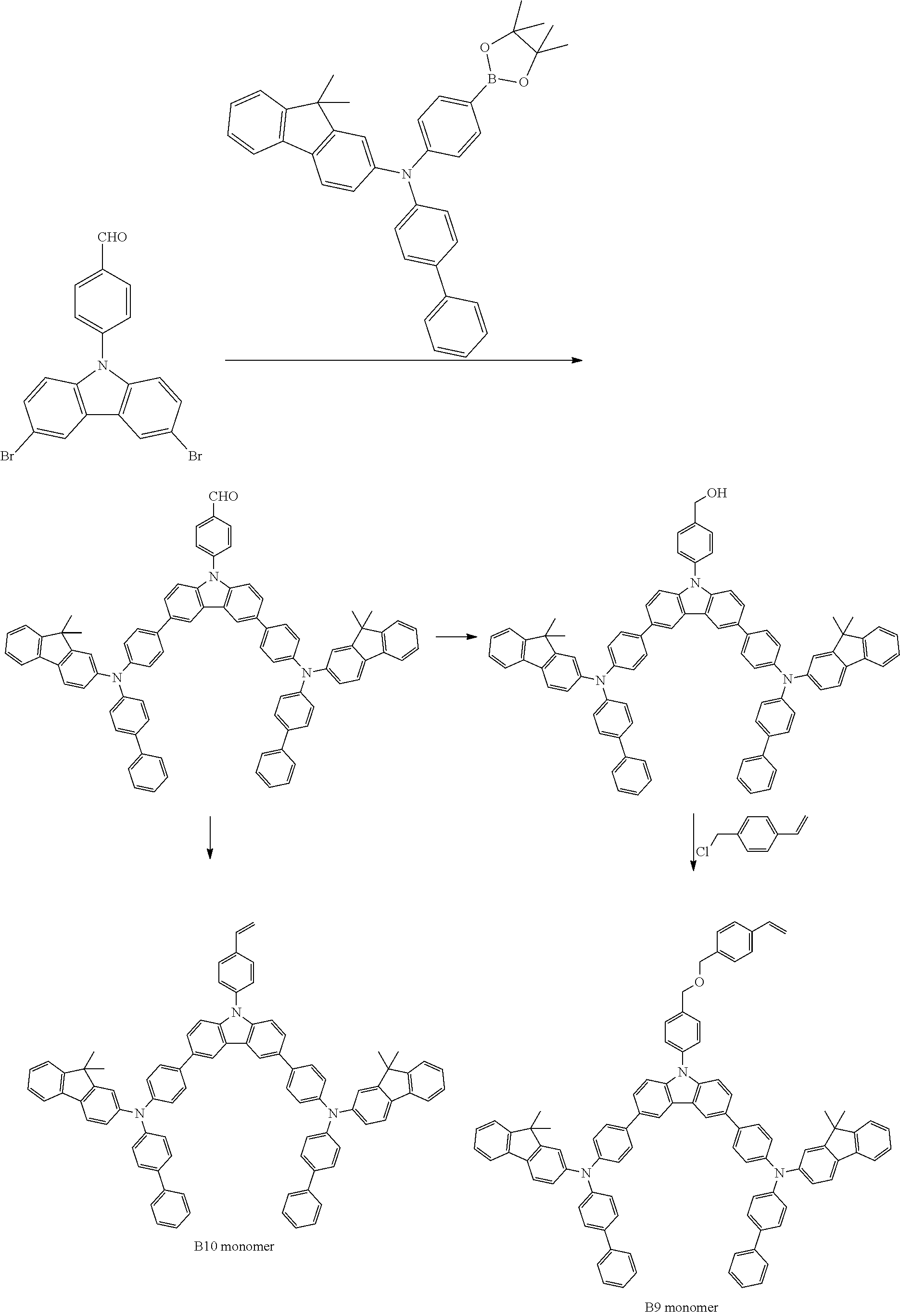

### Synthesis of 4-(3,6-bis(4-([1,1′-biphenyl]-4-yl(9,9-dimethyl-9H-fluoren-2-yl)amino)phenyl)-9H-carbazol-9-yl)benzaldehyde

A mixture of 4-(3,6-dibromo-9H-carbazol-9-yl)benzaldehyde (6.00 g, 17.74 mmol), N-([1,1′-biphenyl]-4-yl)-9,9-dimethyl-N-(4-(4,4,5,5-tetramethyl-1,3,2-dioxaborolan-2-yl)phenyl)-9H-fluoren-2-amine (15.70 g, 35.49 mmol), Pd(PPh3)3 (0.96 g), 7.72 g K2CO3, 100 mL THF and 30 mL H2O was heated at 80° C. under nitrogen overnight. After cooled to room temperature, the solvent was removed under vacuum and the residue was extracted with dichloromethane. The product was then obtained by column chromatography on silica gel with petroleum ether and dichloromethane as eluent, to provide desired product (14.8 g, yield 92%). ¹H NMR (CDCl₃, ppm): 10.14 (s, 1H), 8.41 (d, 2H), 8.18 (d, 2H), 7.86 (d, 2H), 7.71 (dd, 2H), 7.56-7.68 (m, 14H), 7.53 (m, 4H), 7.42 (m, 4H), 7.26-735 (m, 18H), 7.13-7.17 (d, 2H), 1.46 (s 12H).

### (4-(3,6-bis(4-([1,1′-biphenyl]-4-yl(9,9-dimethyl-9H-fluoren-2-yl)amino)phenyl)-9H-carbazol-9-yl)phenyl)methanol

4-(3,6-bis(4-([1,1′-biphenyl]-4-yl(9,9-dimethyl-9H-fluoren-2-yl)amino)phenyl)-9H-carbazol-9-yl)benzaldehyde (10.0 g 8.75 mmol) was dissolved into 80 mL THF and 30 mL ethanol. NaBH₄ (1.32 g 35.01 mmol) was added under nitrogen atmosphere over 2 hours. Then, aqueous hydrochloric acid solution was added until pH 5 and the mixture was kept stirring for 30 min. The solvent was removed under vacuum and the residue was extracted with dichloromethane. The product was then dried under vacuum and used for the next step without further purification.

### Synthesis of B9 Monomer

0.45 g 60% NaH was added to 100 mL dried DMF solution of 10.00 g of (4-(3,6-bis(4-([1,1′-biphenyl]-4-yl(9,9-dimethyl-9H-fluoren-2-yl)amino)phenyl)-9H-carbazol-9-yl)phenyl)methanol. After stirred at room temperature for 1 h, 2.00 g of 1-(chloromethyl)-4-vinylbenzene was added by syringe. The solution was stirred at 60° C. under N2 and tracked by TLC. After the consumption of the starting material, the solution was cooled and poured into ice water. After filtration and washed with water, ethanol and petroleum ether respectively, the crude product was obtained and dried in vacuum oven at 50° C. overnight and then purified by flash silica column chromatography with grads evolution of the eluent of dichloromethane and petroleum ether (1:3 to 1:1). The crude product was further purified by recrystallization from ethyl acetate and column chromatography which enabled the purity of 99.8%. ESI-MS (m/z, Ion): 1260.5811, (M+H)+. ¹H NMR (CDCl₃, ppm): 8.41 (s, 2H), 7.58-7.72 (m, 18H), 7.53 (d, 4H), 7.38-7.50 (m, 12H), 7.25-7.35 (m, 16H), 7.14 (d, 2H), 6.75 (q, 1H), 5.78 (d, 1H), 5.26 (d, 1H), 4.68 (s, 4H), 1.45 (s, 12H).

### Synthesis of B10 Monomer

Under N₂ atmosphere, PPh₃CMeBr (1.45 g 4.0 mmol) was charged into a three-neck round-bottom flask equipped with a stirrer, to which 180 mL anhydrous THF was added. The suspension was placed in an ice bath. Then t-BuOK (0.70 g, 6.2 mmol) was added slowly to the solution, the reaction mixture turned into bright yellow. The reaction was allowed to react for an additional 3 h. After that, 4-(3,6-bis(4-([1,1′-biphenyl]-4-yl(9,9-dimethyl-9H-fluoren-2-yl)amino)phenyl)-9H-carbazol-9-yl)benzaldehyde (2.0 g, 1.75 mmol) was charged into the flask and stirred at room temperature overnight. The mixture was quenched with 2N HCl, and extracted with dichloromethane, and the organic layer was washed with deionized water three times and dried over anhydrous Na₂SO₄. The filtrate was concentrated and purified on silica gel column using dichloromethane and petroleum ether (1:3) as eluent. The crude product was further recrystallized from dichloromethane and ethyl acetate with purity of 99.8%. ESI-MS (m/z, Ion): 1140.523, (M+H)⁺. ¹HNMR (CDCl₃, ppm): 8.41 (s, 2H), 7.56-7.72 (m, 18H), 7.47-7.56 (m, 6H), 7.37-7.46 (m, 6H), 7.23-7.36 (m, 18H), 6.85 (q, 1H), 5.88 (d, 1H), 5.38 (d, 1H), 1.46 (s, 12H).

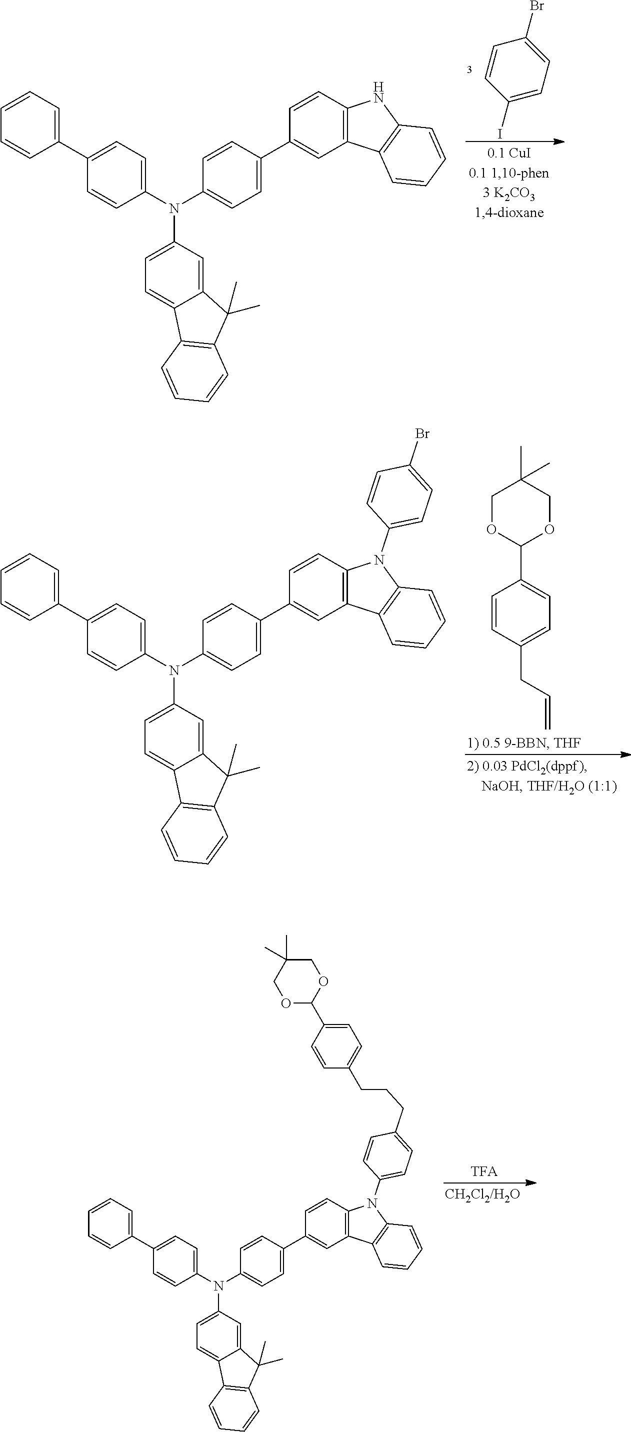 [SMILES: CC1(C)c2ccccc2-c2ccc(N(c3ccc(-c4ccccc4)cc3)c3ccc(-c4ccc5[nH]c6ccccc6c5c4)cc3)cc21 ; Brc1ccc(I)cc1 ; CC1(C)c2ccccc2-c2ccc(N(c3ccc(-c4ccccc4)cc3)c3ccc(-c4ccc5c(c4)c4ccccc4n5-c4ccc(Br)cc4)cc3)cc21 ; C=CCc1ccc(C2OCC(C)(C)CO2)cc1 ; CC1(C)COC(c2ccc(CCCc3ccc(-n4c5ccccc5c5cc(-c6ccc(N(c7ccc(-c8ccccc8)cc7)c7ccc8c(c7)C(C)(C)c7ccccc7-8)cc6)ccc54)cc3)cc2)OC1]

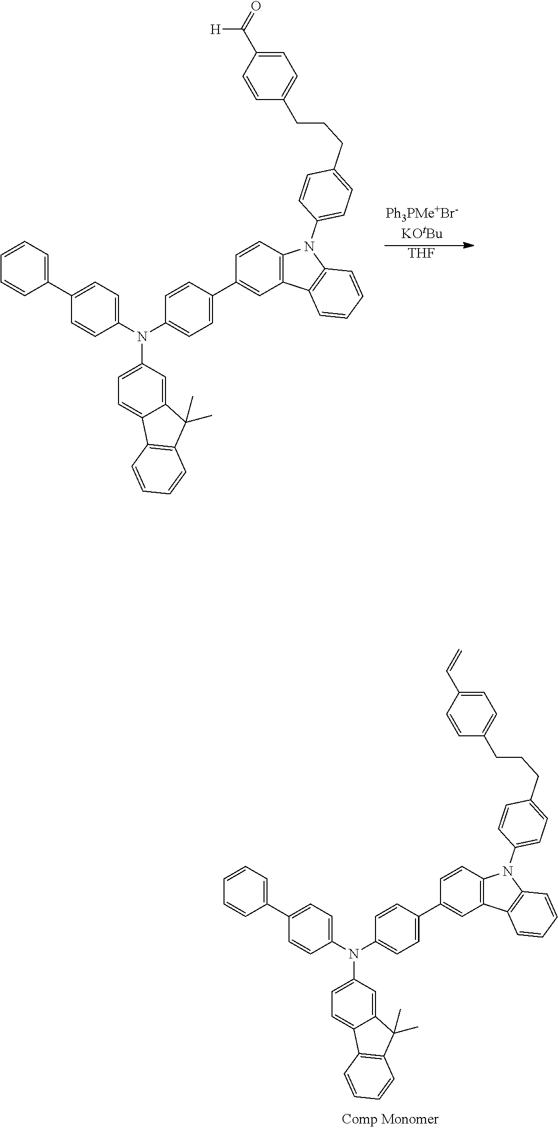 [SMILES: "THF" ; CC1(C)c2ccccc2-c2ccc(N(c3ccc(-c4ccccc4)cc3)c3ccc(-c4ccc5c(c4)c4ccccc4n5-c4ccc(CCCc5ccc(C=O)cc5)cc4)cc3)cc21 ; C=Cc1ccc(CCCc2ccc(-n3c4ccccc4c4cc(-c5ccc(N(c6ccc(-c7ccccc7)cc6)c6ccc7c(c6)C(C)(C)c6ccccc6-7)cc5)ccc43)cc2)cc1]

### Synthesis of N-([1,1′-biphenyl]-4-yl)-N-(4-(9-(4-bromophenyl)-9H-carbazol-3-yl)phenyl)-9,9-dimethyl-9H-fluoren-2-amine

In a glovebox, a 100 mL round bottomed flask was charged with added the N-(4-(9H-carbazol-3-yl)phenyl)-N-([1,1′-biphenyl]-4-yl)-9,9-dimethyl-9H-fluoren-2-amine (2.55 g 4.24 mmol),¹ 4-bromoiodobenzene (4.00 g 12.7 mmol), K₂CO₃ (1.76 g, mmol), and CuI (161 mg 0.847 mmol). The solid mixture was diluted with 50 mL dioxane and stirred for 15 minutes. A 5 mL dioxane solution of 1,10-phenanthroline (153 mg 0.847 mmol) was added and the mixture heated to 120° C. for 2 days. After cooling to room temperature, the organic solvents were removed by rotary evaporation and the residue dissolved in 100 mL CH₂Cl₂ and 100 mL H₂O. The organic fraction was collected and the aqueous layer washed with CH₂Cl₂ (2×100 mL). The organic fractions were combined and dried with MgSO₄. After filtration, the solvents were removed by rotary evaporation and the product purified by Si gel column chromatography 30% CH₂Cl₂ in hexanes (Yield=1.50 g, 42.10/%). NMR spectroscopy of the products indicated the presence of two species which was supported with MS as a mixture of bromo and iodo products. ¹H NMR (CDCl₃): δ 1.46 (s, 6H), 7.25-7.62 (m, 28H), 8.17 (d, J=8H, 1H), 8.25 (d, J=8 Hz, 1H), 8.35 (br s, 1H). ¹³C{¹H} NMR (CDCl₃): δ 27.1, 46.9, 92.1, 109.7, 109.8, 118.4, 119.5, 120.4, 120.5, 120.9, 122.5, 123.6, 124.1, 125.3, 126.3, 126.7, 126.8, 127.0, 127.9, 128.6, 128.8, 133.2, 136.8, 139.1, 139.9, 141.1.

### Synthesis of N-([1,1′-biphenyl]-4-yl)-N-(4-(9-(4-(3-(4-(5,5-dimethyl-1,3-dioxan-2-yl)phenyl)propyl) phenyl)-9H-carbazol-3-yl)phenyl)-9,9-dimethyl-9H-fluoren-2-amine

To a 20 mL Scintillation vial was added 2-(4-allylphenyl)-5,5-dimethyl-1,3-dioxane (1.40 g, 6.03 mmol) and 5 mL THF. The 9-BBN dimer (0.736 g, 3.01 mmol) was weighed into a separate vial and dissolved in 5 mL THF. This solution was carefully added dropwise to the allylbenzene and the mixture was stirred for 1 day at room temperature. Separately, a 100 mL rbf was charged with PdCl₂dppf (74 mg 0.101 mmol) and N-([1,1′-biphenyl]-4-yl)-N-(4-(9-(4-bromophenyl)-9H-carbazol-3-yl)phenyl)-9,9-dimethyl-9H-fluoren-2-amine (2.54 g 3.35 mmol). The solids were dissolved in 30 mL THF followed by the addition of aqueous NaOH (30 mL, 402 mg 10.1 mmol). To this stirring solution was added the 9-BBN-allylbenzene solution and the mixture refluxed overnight at 85° C. Upon cooling the organic fraction was separated and the aqueous layer washed several times with ether (2×50 mL). The organic fractions were combined and dried with MgSO₄. After removal of the solvent by rotary evaporation the product was purified by Si gel column chromatography with 50% ethyl acetate in hexanes (Yield=2.89 g, 94.7%). ¹HNMR (CDCl₃): δ 0.80 (s, 3H), 1.31 (s, 3H), 1.45 (s, 6H), 2.05 (m, 2H), 2.75 (m, 4H), 3.64 (m, 2H), 3.76 (m, 2H), 5.39 (s, 1H), 7.14 (dd, J=4, 8 Hz, 1H), 7.25-7.32 (m, 11H), 7.40-7.54 (m, 14H), 7.60-7.67 (m, 7H), 8.18 (dd, J=4, 8 Hz, 1H), 8.35 (d, J=4 Hz, 1H). ¹³C{¹H} NMR (CDCl₃): δ 21.9, 23.1, 27.1, 30.2, 32.8, 35.0, 35.3, 42.0, 46.9, 101.8, 110.0, 110.1, 118.3, 118.8, 119.5, 119.9, 120.3, 120.7, 122.5, 123.4, 123.6, 123.8, 123.9, 124.6, 125.1, 126.0, 126.2, 126.5, 126.7, 126.8, 126.9, 127.0, 127.8, 128.0, 129.8, 132.8, 134.4, 135.1, 135.3, 136.2, 136.5, 139.0, 140.3, 140.7, 141.5, 141.7, 142.8, 146.4, 147.1, 147.3, 153.6, 155.2.

### Synthesis of 4-(3-(4-(3-(4-([1,1′-biphenyl]-4-yl(9,9-dimethyl-9H-fluoren-2-yl)amino)phenyl)-9H-carbazol-9-yl)phenyl)propyl)benzaldehyde

A 100 mL round bottomed flask was charged with N-([1,1′-biphenyl]-4-yl)-N-(4-(9-(4-(3-(4-(5,5-dimethyl-1,3-dioxan-2-yl)phenyl)propyl)phenyl)-9H-carbazol-3-yl)phenyl)-9,9-dimethyl-9H-fluoren-2-amine (3) (2.75 g, 3.02 mmol) and 30 mL CH₂Cl₂. Trifluoroacetic acid (4 mL) and water (0.3 mL) were added dropwise at room temperature and the mixture stirred overnight. Saturated NaHCO₃ was added carefully to the reaction mixture until no more gas evolved. The aqueous phase was washed several times with CH₂Cl₂ (2×50 mL) and the organic fractions combined. After drying with MgSO₄, the solution was filtered and the solvent removed by rotary evaporation. The product was further purified by Si gel chromatography with 50% ethyl acetate in hexanes (Yield=2.40 g, 96.4%). ¹HNMR(CDCl₃): δ 1.46 (s, 6H), 2.10 (m, 2H), 2.82 (m, 4H), 7.13 (m, dd, J=4, 8 Hz), 7.25-7.32 (m, 231), 7.41 (m, 7H), 7.84 (d, J=8 Hz, 2H), 8.19 (d, J=8 Hz, 1H), 8.36 (d, J=4 Hz, 1H), 10.00 (s, 1H)¹³C{¹H} NMR(CDCl₃): δ27.1, 32.5, 35.1, 35.7, 46.9, 109.9, 110.0, 118.3, 118.9, 119.5, 120.0, 120.3, 120.7, 122.5, 123.1, 123.8, 124.5, 125.1, 126.0, 126.5, 126.8, 127.0, 127.8, 128.0, 128.8, 129.1, 129.8, 130.0, 132.9, 134.7, 134.7, 135.5, 140.3, 140.6, 141.2, 141.4, 149.5, 153.6, 191.9.

### Synthesis of N-([1,1′-biphenyl]-4-yl)-9,9-dimethyl-N-(4-(9-(4-(3-(4-vinylphenyl)propyl)phenyl)-9H-carbazol-3-yl)phenyl)-9H-fluoren-2-amine (Comp Monomer)

A 100 mL round bottomed flask vial was charged with methyltriphenylphosphonium bromide (2.88 g, 8.05 mmol) and 10 mL dry THF. Solid potassium tert-butoxide (1.13 g, 10.1 mmol) was added in one portion and the mixture stirred for 15 minutes at room temperature. A THF (30 mL) solution of 4-(3-(4-(3-(4-([1,1′-biphenyl]-4-yl(9,9-dimethyl-9H-fluoren-2-yl)amino)phenyl)-9H-carbazol-9-yl)phenyl)propyl)-benzaldehyde (4) (3.32 g, 4.02 mmol) was added dropwise to the mixture which was stirred overnight. The reaction was cautiously quenched with water and extracted with 100 mL CH₂Cl₂. The aqueous layer was further extracted with CH₂Cl₂ (2×100 mL) and the organic fractions combined. After drying with MgSO₄, the solvent was removed by rotary evaporation and the product purified by Si gel chromatography (5% CH₂Cl₂ in hexanes (Yield=3.05 g, 92.1%). ¹H NMR (CDCl₃): δ 1.45 (s, 6H), 2.08 (m, 2H), 2.74 (m, 4H), 5.21 (dd, J=2.4 Hz, 1H), 5.73 (dd, J=2.4 Hz, 1H), 6.7 (dd, J=4, 6 Hz, 1H), 7.19 (m, 1H), 7.24-7.51 (m, 26H), 7.60-7.67 (m, H), 8.18 (d, J=8 Hz, 1H), 8.36 (d, J=4 Hz, 1H). ¹³C{¹H} NMR (CDCl₃): δ27.1, 32.8, 35.1, 35.2, 46.9, 110.0, 110.1, 113.0, 118.3, 118.9, 119.5, 119.9, 120.3, 120.7, 122.5, 123.4, 123.6, 123.8, 123.9, 124.6, 125.1, 126.0, 126.3, 126.5, 126.7, 126.8, 126.9, 127.0, 127.8, 128.0, 128.6, 128.8, 128.0, 128.6, 128.8, 132.8, 134.4, 135.1, 135.3, 135.4, 136.4, 136.7, 139.0, 140.3, 140.7, 141.5, 141.7, 141.8, 146.4, 147.1, 147.3, 153.6, 155.2.

### General Protocol for Radical Polymerization of Charge Transporting B Monomers:

In a glovebox, B monomer (1.00 equiv) was dissolved in anisole (electronic grade, 0.25 M). The mixture was heated to 70° C., and AIBN solution (0.20 M in toluene, 5 mol %) was injected. The mixture was stirred until complete consumption of monomer, at least 24 hours (2.5 mol % portions of AIBN solution can be added to complete conversion). The polymer was precipitated with methanol (10× volume of anisole) and isolated by filtration. The filtered solid was rinsed with additional portions of methanol. The filtered solid was re-dissolved in anisole and the precipitation/filtration sequence repeated twice more. The isolated solid was placed in a vacuum oven overnight at 50° C. to remove residual solvent.

### Charge Transporting B Polymer Structures and Molecular Weights (MW)

Mₙ: Number-averaged MW; M_{w}: Weight-averaged MW; M_{z}: Z-averaged MW; M_{z+1}: Z+1-averaged MW. PDI=M_{w}/Mₙ: Polydispersity

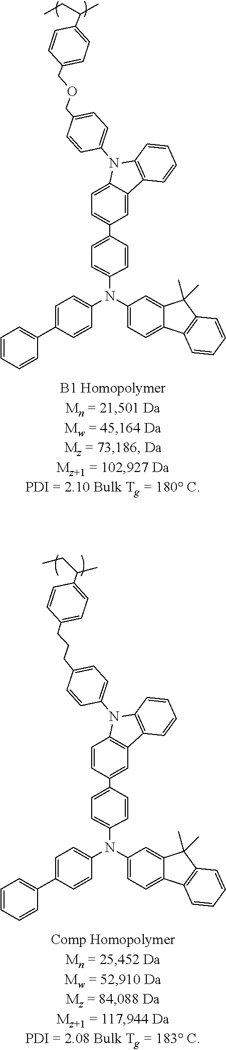

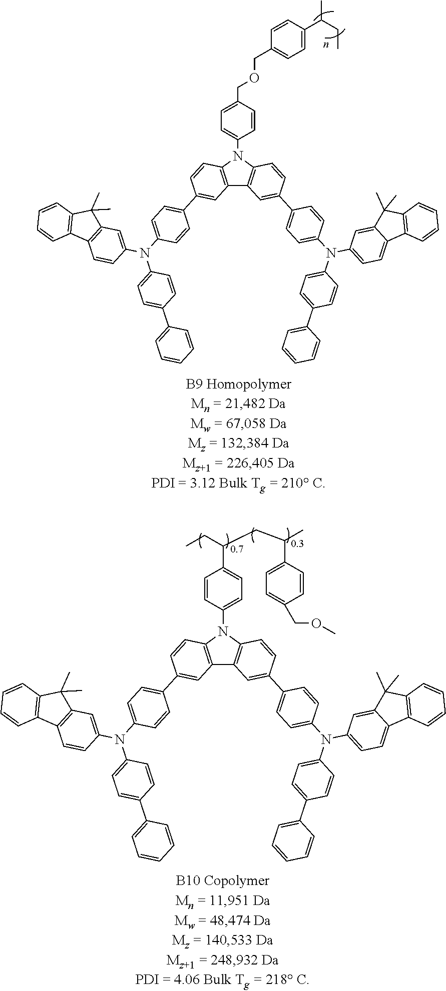

Underlying acid Hole Injection Layer (HIL) Polymer Structures

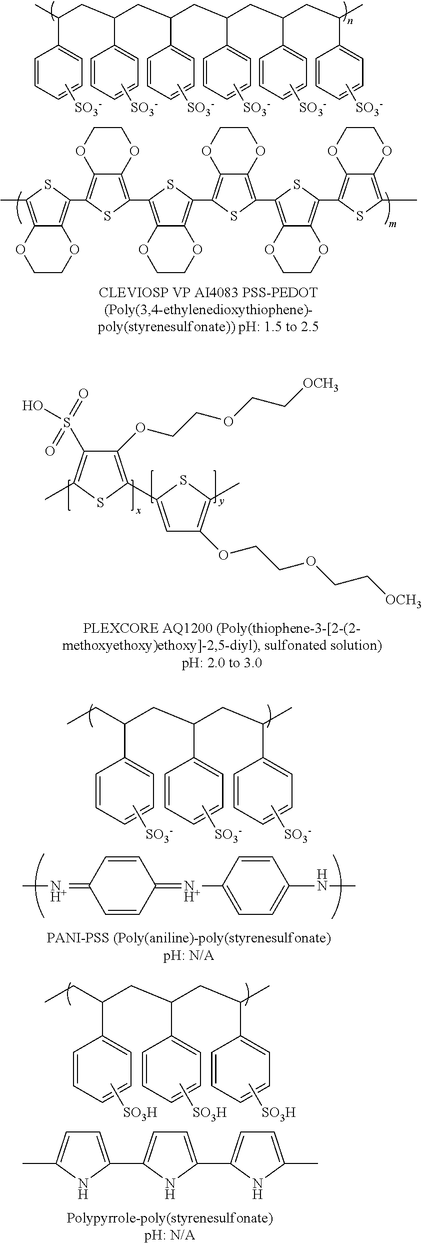

Table of CLEVIOS PSS-PEDOT Products

| | Solid | | Viscosity at | Particle | Conductivity |
|---|---|---|---|---|---|
| | content | PEDOT:PSS | 20° C. | size | (S/cm) |
| Trade Name | (wt %) | (w:w) | (mPa · s) | (nm) | (+5 wt % DMSO) |
| CLEVIOS ™ PH500 | 1.1 | 1:2.5 | 25 | 30 | 500 |
| CLEVIOS ™ PH750 | 1.1 | 1:2.5 | 25 | 30 | 750 |
| CLEVIOS ™ PH1000 | 1.1 | 1:2.5 | 30 | 30 | 1000 |
| CLEVIOS ™ P | 1.3 | 1:2.5 | 80 | 90 | 80 |
| CLEVIOS ™ PH | 1.3 | 1:2.5 | 25 | 30 | 30 |
| CLEVIOS ™ P VP AI | 1.3-1.7 | 1:6 | 5-12 | 80-100 | 500-5000 |
| 4083 | | | | | |
| Aldrich 560596 PSS- | 2.8 | 1:18.6 | <20 | <200 nm | IE−5 |
| PEDOT | | | | | |

CLEVIOS P VP AI4083 is preferred for OLED application.

General Experimental Procedures for Hole Transporting Layer (HTL)/Hole Injection Layer

(HIL) Manufacturing, Thermal Cross-Linking and Strip Tests

1) Preparation of HTL solution: Charge transporting B polymer solid powders were directly dissolved into anisole to make a 1, 2, 4 wt % stock solution. In the case of charge transporting B homopolymer, the solution was stirred at 80° C. for 5 to 10 min in N₂ for complete dissolving
2) Preparation of thermally annealed acidic HIL film (1^{st} layer): Si wafer was pre-treated by UV-ozone for 4 min prior to use. In the case of dispersion of acidic PSS-PEDOT in water (CLEVIOS P VP AI4083 purchased from Helms), the dispersion was filtered via 0.2 m Nylon filter. In the case of solution of acidic PLEXCORE AQ1200 in solvents (PLEXCORE OC AQ1200 purchased from Solvay), the solution was filtered via 0.45 μm PDVF filter. Then, several drops of the above filtered HIL formulation were deposited onto the pre-treated Si wafer. The thin film was obtained by spin coating at 250 rpm for 5 s and then 2000 rpm for 60 s. The resulting film was then transferred into the N₂ purging box. The “w” film was prebaked at 100° C. for 1 min to remove most of residual solvent Subsequently, the HIL film was thermally annealed at 170° C. for 15 min.
3) Preparation of thermally cross-linked HTL polymer film (2^{nd} layer): The above HTL, solution was filtered through 0.2 μm PTFE syringe filter and then several drops of the filtered HTL solution were deposited onto the above annealed HIL layer. The HTL thin film was obtained by spin coating at 500 rpm for 5 s and then 2000 rpm for 30 s. The resulting film was then transferred into the N₂ purging box. The “wet” film was prebaked at 100° C. for 1 min to remove most of residual anisole. Subsequently, the film was thermally cross-linked at 160 to 220° C. for 20 min.
4) Strip test on thermally cross-linked HIL polymer film: The “Initial” thickness of thermally cross-linked HTL film was measured using an M-2000D ellipsometer (J. A Woollam Co., Inc.). Then, several drops of o-xylene or anisole w added onto the film to form a puddle. After 90 s, the solvent was spun off at 3500 rpm for 30 s. The “Strip” thickness of the film was immediately measured using the ellipsometer. The film was then transferred into the N₂ paging box, followed by post-baking at 100° C. for 1 min to remove any swollen solvent in the film. The “Final” thickness was measured using the ellipsometer. The film thickness was determined using Gen-Osc model and averaged over 9=3×3 points in a 1 cm×1 cm area
“−Strip”=“Strip”−“Initial”: Initial film loss due to solvent strip
“−PSB”=“Fine”−“Strip”: Further film loss of swelling solvent
“−Total”=“−Strip”+“−PSB”=“Final”−“Initial”: Total film loss due to solvent strip and swelling
Strip tests were applied for studying thermal cross-linking of HTL polymers on top of annealed acidic HIL layer. For a fully cross-linked HTL film with good solvent resistance, the total film loss after o-xylene or anisole stripping should be <1 nm, preferably <0.5 nm.

### Example 1 Comp Homopolymer Thermal Cross-Linking as Control

High MW Comp homopolymer gives 25 to 40% film loss to o-xylene stripping and gives almost 100% film loss to anisole stripping after 205° C./20 min cross-linking on top of acidic HIL. This indicates that there is no thermal cross-linking occurred, as evidenced by anisole strip test results.

The absence of thermal cross-linking can be attributed to the absence of benzyloxy functional group in Comp homopolymer.

TABLE 1
Strip tests of high MW Comp homopolymer cross-linked at 205° C. for 20 min

| HIL | Strip Solvent | Initial (nm) | Strip (nm) | −Strip (nm) | Final (nm) | −PSB (nm) | −Total (nm) |
|---|---|---|---|---|---|---|---|
| PLEXCORE | o-xylene | 36.56 ± 0.28 | 23.40 ± 0.56 | −13.16 | 22.99 ± 0.69 | −0.41 | −13.57 |
| AQ1200 | anisole | 36.56 ± 0.28 | 1.40 ± 0.16 | −35.16 | 1.29 ± 0.17 | −0.11 | −35.27 |
| PSS-PEDOT | o-xylene | 36.05 ± 0.29 | 27.73 ± 1.52 | −8.32 | 27.15 ± 0.86 | −0.58 | −8.90 |
| AI4083 | anisole | 36.05 ± 0.29 | 4.30 ± 0.25 | −31.75 | 3.61 ± 0.36 | −0.69 | −32.44 |

### Example 2 Effect of HIL Acidity on Catalyzing B Polymer Thermal Cross-Linking

High MW B1 homopolymer gives no film loss to o-xylene stripping and gives <20% film loss to anisole stripping after 205° C./20 min cross-linking on top of acidic HIL. Medium MW B10 copolymer gives no film loss to o-xylene stripping and gives 60 to 80% film loss to anisole stripping after 205° C./20 min cross-linking on top of acidic HIL.

This indicates that acidic HIL on the interface can initiate and catalyze the benzyloxy cross-inking in HTL thin film. More film loss is seen for anisole stripping because anisole is a much stronger solvent for HTL polymer than o-xylene.

Overall, PSS-PEODT AI4083 performs better than Plexoore AQ1200 in term of initiating and catalyzing the benzyloxy cross-linking in HIL thin film, as evidenced by the anisole strip test results. This can be attributed to the stronger acidity of PSS-PEODT AI4083 than Plexoore AQ1200.

Overall, high MW B1 homopolymer performs better than medium MW B10 copolymer in terms of anisole resistance. This can be attributed to the lower T_{g} of B1 homopolymer (180° C.) than that of B10 copolymer (218° C.), which is lower than the annealing temperature (205° C.). This greatly improves the proton mobility in HIL film for enhanced catalytic effect

TABLE 2
Strip tests of high MW B1 homopolymer medium MW B10 copolymer cross-linked at 205° C. for 20 min

| | | | | | | | |
|---|---|---|---|---|---|---|---|
| HIL | Strip Solvent | Initial (nm) | Strip (nm) | −Strip (nm) | Final (nm) | −PSB (nm) | −Total (nm) |

High MW B1 homopolymer

| | | | | | | | |
|---|---|---|---|---|---|---|---|
| PLEXCORE | o-xylene | 36.85 ± 0.29 | 36.94 ± 0.56 | +0.09 | 36.67 ± 0.44 | −0.27 | −0.18 |
| AQ1200 | anisole | 36.67 ± 0.44 | 29.94 ± 0.66 | −6.73 | 30.25 ± 0.66 | +0.30 | −6.42 |
| PSS-PEDOT | o-xylene | 38.11 ± 0.18 | 38.84 ± 0.27 | +0.73 | 38.32 ± 0.34 | −0.52 | +0.21 |
| AI4083 | anisole | 38.32 ± 0.34 | 36.50 ± 0.35 | −1.82 | 35.71 ± 0.31 | −0.79 | −2.61 |

Medium MW B10 copolymer

| | | | | | | | |
|---|---|---|---|---|---|---|---|
| PLEXCORE | o-xylene | 41.49 ± 0.45 | 42.03 ± 0.48 | +0.54 | 41.47 ± 0.54 | −0.56 | −0.02 |
| AQ1200 | anisole | 41.47 ± 0.54 | 8.92 ± 0.41 | −32.55 | 8.99 ± 0.32 | 0.07 | −32.48 |
| PSS-PEDOT | o-xylene | 42.75 ± 0.20 | 43.31 ± 0.22 | +0.56 | 42.53 ± 0.10 | −0.78 | −0.22 |
| AI4083 | anisole | 42.53 ± 0.10 | 18.00 ± 0.61 | −24.53 | 17.93 ± 0.71 | −0.07 | −24.60 |

### Example 3 Effect of Temperature on Acidic HIL Catalyzed B1 Polymer Benzyloxy Thermal Cross-Linking

High MW B1 homopolymer gives <5% and no film loss to o-xylene stripping alter 160° C. and 180 to 220° C./20 min cross-inking on top of acidic HIL, respectively.

High MW B1 homopolymer gives almost 100% and <7% film loss to anisole stripping after 160° C. and 180 to 220° C./20 min cross-linking on top of acidic HIL, respectively. B1 homopolymer gives good anisole resistance after 220° C./20 min cross-linking with <0.5 nm film loss.

This indicates that acidic HIL on the interface can initiate and catalyze the benzyloxy cross-linking in B1 homopolymer thin film upon annealing at 160 to 220° C., especially at 205 to 220° C. as evidenced by the more aggressive anisole strip test results.

The significant improvement on benzyloxy cross-linking at ≥205° C. can be attributed to the significantly enhanced proton mobility in HTL film when the annealing temperature is higher than its T_{g} (B1 homopolymer T_{g}: 180° C.).

TABLE 3
Strip tests of high MW B1 homopolymer cross-linked at 160 to 220° C. for 20 min

| | | | | | | | |
|---|---|---|---|---|---|---|---|
| HIL | Strip Solvent | Initial (nm) | Strip (nm) | −Strip (nm) | Final (nm) | −PSB (nm) | −Total (nm) |

160° C./20 min Thermal Cross-Linking

| | | | | | | | |
|---|---|---|---|---|---|---|---|
| PSS-PEDOT | o-xylene | 43.42 ± 0.18 | 42.16 ± 0.28 | −1.26 | 41.84 ± 0.20 | −0.32 | −1.58 |
| AI4083 | anisole | 41.84 ± 0.20 | 4.66 ± 0.17 | −37.17 | 4.22 ± 0.08 | −0.45 | −37.62 |

180° C./20 min Thermal Cross-Linking

| | | | | | | | |
|---|---|---|---|---|---|---|---|
| PSS-PEDOT | o-xylene | 40.99 ± 0.18 | 42.40 ± 0.18 | +1.41 | 41.17 ± 0.21 | −1.23 | +0.19 |
| AI4083 | anisole | 41.17 ± 0.21 | 5.36 ± 0.14 | −35.81 | 5.37 ± 0.11 | +0.01 | −35.80 |

205° C./20 min Thermal Cross-Linking

| | | | | | | | |
|---|---|---|---|---|---|---|---|
| PSS-PEDOT | o-xylene | 38.11 ± 0.18 | 38.84 ± 0.27 | +0.473 | 38.32 ± 0.34 | −0.52 | +0.21 |
| AI4083 | anisole | 38.32 ± 0.34 | 36.50 ± 0.35 | −1.82 | 35.71 ± 0.31 | −0.79 | −2.61 |

220° C./20 min Thermal Cross-Linking

| | | | | | | | |
|---|---|---|---|---|---|---|---|
| PSS-PEDOT | o-xylene | 36.49 ± 0.20 | 38.29 ± 0.33 | +1.80 | 37.08 ± 0.10 | −1.21 | +0.59 |
| AI4083 | anisole | 37.08 ± 0.10 | 37.52 ± 0.21 | +0.44 | 36.93 ± 0.11 | −0.59 | −0.15 |

### Example 4 Effect of Film Thickness on Acidic HIL Catalyzed B1 Homopolymer Benzyloxy Thermal Cross-Linking

High MW B1 homopolymer gives no film loss to o-xylene stripping after 205° C./20 min cross-linking on top of acidic HIL for up to 100 nm film thickness.
High MW B1 homopolymer gives increasing film loss but still <10% film loss to anisole stripping after 205° C./20 min cross-linking on tap of acidic HIL for up to 100 nm film thickness. For B1 homopolymer film with 20 nm thickness, it gives good anisole resistance after 205° C./20 min cross-linking with ca 1 nm film loss.
This indicates that acidic HIL-catalyzed benzyloxy thermal cross-linking can be effective for a wide range of film thickness.

TABLE 4
Strip tests of high MW B1 homopolymer cross-linked at 205° C. for 20 min

| HIL | Strip Solvent | Initial (nm) | Strip (nm) | −Strip (nm) | Final (nm) | −PSB (nm) | −Total (nm) |
|---|---|---|---|---|---|---|---|
| PSS-PEDOT | o-xylene | 20.43 ± 0.15 | 20.51 ± 0.11 | +0.08 | 20.22 ± 0.25 | −0.29 | −0.21 |
| AI4083 | anisole | 20.22 ± 0.25 | 19.48 ± 0.20 | −0.74 | 19.02 ± 0.10 | −0.46 | −1.20 |
| PSS-PEDOT | o-xylene | 38.11 ± 0.18 | 38.84 ± 0.27 | +0.47 | 38.32 ± 0.34 | −0.52 | +0.21 |
| AI4083 | anisole | 38.32 ± 0.34 | 36.50 ± 0.35 | −1.82 | 35.71 ± 0.31 | −0.79 | −2.61 |
| PSS-PEDOT | o-xylene | 97.60 ± 0.33 | 98.97 ± 0.24 | +1.36 | 97.84 ± 0.34 | −1.12 | +0.24 |
| AI4083 | anisole | 97.84 ± 0.34 | 92.31 ± 0.35 | −5.53 | 89.37 ± 0.78 | −2.95 | −8.48 |

### Example 5 Effect of Acidic HIL Film Annealing Temperature on B1 Homopolymer Benzyloxy Thermal Cross-Linking

High MW B1 homopolymer gives no film loss to o-xylene stripping after 150° C./20 min or 170° C./15 min annealing for HIL and 205° C./20 min cross-linking for HTL.
High MW B1 homopolymer gives less film loss to anisole stripping after 150° C./20 min annealing for HIL and 205° C./20 min cross-inking for B1 than after 170° C./15 min annealing for HIL and 205° C./20 min cross-inking for B1.
This indicates that lower HIL annealing temperature favors the benzyloxy cross-linking.

TABLE 5
Strip tests of high MW B1 homopolymer cross-linked at 205°C. for 20 min

| | HIL | | | | | | | |
|---|---|---|---|---|---|---|---|---|
| HIL | Annealing | Strip Solvent | Initial (nm) | Strip (nm) | −Strip (nm) | Final (nm) | −PSB (nm) | −Total (nm) |
| PLEXCORE | 170° C. 15 min | o-xylene | 36.85 ± 0.29 | 36.94 ± 0.56 | +0.09 | 36.67 ± 0.44 | −0.27 | −0.18 |
| AQ1200 | 170° C. 15 min | anisole | 36.67 ± 0.44 | 29.94 ± 0.66 | −6.73 | 30.25 ± 0.66 | +0.30 | −6.42 |
| PLEXCORE | 150° C. 20 min | o-xylene | 31.75 ± 0.30 | 32.15 ± 0.19 | +0.40 | 31.90 ± 0.27 | −0.25 | +0.15 |
| AQ1200 | 150° C. 20 min | anisole | 31.90 ± 0.27 | 29.30 ± 0.30 | −2.60 | 29.22 ± 0.47 | −0.08 | −2.68 |

### General Experimental Procedures for OLED Device Manufacturing and Testing

The following types of OLED devices were fabricated to evaluate electroluminescent (EL) performances of thermally cross-linked HTL layer.
TypeA ITO/AQ1200/HTL molecule (evaporative, 400 Å)/EML/ETL/Al
TypeB: ITO/AQ1200/HIL polymer (soluble, 400 Å)/EML/ETL/Al

The thicknesses of HIL, EML, ETL and cathode Al are 470, 400, 350 and 800 Å, respectively. Type A device was fabricated with evaporated HTL (same HTL core as HTL polymer) as evaporative control; Type B device was fabricated with solution processed HTL polymer for comparison. Current density-voltage (J-V) characteristics, luminescence efficiency versus luminance curves, and luminescence decay curves of Type A-B devices were measured to evaluate the key device performance, specifically the driving voltage (at 1000 nit), current efficiency (at 1000 nit) and lifetime (15000 nit, after 10 hr). Type A-B Hole-Only Device (HOD) without EMI., and ETL layers were also prepared and tested for evaluating the hole mobility of the cross-linked HTL.

### Example 6 OLED Device Performance from Thermally Cross-Linked HTL Polymer

In the full OLED device, thermally cross-linked B1 Homopolymer and B9 Homopolymer gives comparable performance to the evaporative control in term of driving voltage, efficiency, color quality (CIE) and lifetime.
In the HOD device, thermally cross-linked B1 Homopolymer and B9 Homopolymer gives compared hole mobility to the evaporative control in term of driving voltage.

TABLE 6
Summary table on high MW B1 Homopolymer as HTL in OELD and HOD device

| | | | | | | | Lifetime | |
|---|---|---|---|---|---|---|---|---|
| OLED | Device Structure | | | Voltage [V, | Efficiency | | [%, 10 hr] | EL |
| Device | HIL | HTL | EML | 1000 nit] | [cd/A] | CIE | 15000 nit | [nm] |
| Control | Plexcore | Evap. HTL-70 | HP405:Ir1A18 | 3.0 | 54.2 | 318 629 | 97.5 | 516 |
| | AQ1200 | | (15%) | | | | | |
| Sample | | B1 | | 3.2 | 67.2 | 314 630 | 94.3 | 516 |
| | | Homopolymer | | | | | | |
| Sample | | B9 | | 3.0 | 62.7 | 313 630 | 96.7 | 516 |
| | | Homopolymer | | | | | | |

| HOD | Device Structure | | Voltage |
|---|---|---|---|
| Device | HIL | HTL | [10/100 mA/cm²] |
| Control | Plexcore | Evap. HTL-70 | 1.6/4.0 |
| Sample | AQ1200 | B1 | 2.1/5.6 |
| | | Homopolymer | |
| Sample | | B9 | 1.4/3.9 |
| | | Homopolymer | |

1. A method for producing an organic charge transporting film; said method comprising steps of: (a) applying to a substrate a first polymer resin which has substituents which are sulfonic acids, sulfonic acid salts or esters of sulfonic acids; and (b) applying over the first polymer resin a second polymer resin having M_{w} at least 3,000 and comprising arylmethoxy linkages.

2. The method of claim 1 in which the second polymer resin has M_{w} from 5,000 to 100,000.

3. The method of claim 2 in which the second polymer resin comprises at least 50 wt % polymerized units of a monomer having from 6 to 20 aromatic rings.

4. The method of claim 3 in which the first polymer resin has M_{w} from 2,000 to 1,000,000.

5. The method of claim 4 in which the second polymer resin comprises at least 50 wt % polymerized units of a monomer of formula NAr¹Ar²Ar³, wherein Ar¹, Ar² and Ar³ independently are C₆-C₅₀ aromatic substituents and at least one of Ar¹, Ar² and Ar³ contains a vinyl group attached to an aromatic ring.

6. The method of claim 5 in which the first polymer resin comprises a first polymer comprising polymerized units of styrene substituted by sulfonic acid, sulfonic acid salt or sulfonic acid ester substituents.

7. The method of claim 6 in which the first polymer resin comprises a second polymer which does not comprise polymerized units of styrene substituted by sulfonic acid, sulfonic acid salt or sulfonic acid ester substituents.

8. The method of claim 7 in which the second polymer comprises polymerized units of a monomer comprising an aromatic ring.

9. The method of claim 8 in which the coated surface is heated to a temperature from 140 to 230° C.

10. An electronic device comprising one or more organic charge transporting films made by the method of claim 1.

11. A light emitting device comprising one or more organic charge transporting films made by the method of claim 1.
